(19) United States
(12) Patent Application Publication
(10) Pub. No.: US 2016/0233284 A1
(43) Pub. Date: Aug. 11, 2016

(54) ORGANIC EL DEVICE AND ELECTRONIC APPARATUS

(71) Applicant: SEIKO EPSON CORPORATION, Tokyo (JP)

(72) Inventors: Yuki HANAMURA, Shiojiri-shi (JP); Koya SHIRATORI, Matsumoto-shi (JP)

(73) Assignee: SEIKO EPSON CORPORATION, Tokyo (JP)

(21) Appl. No.: 15/009,136

(22) Filed: Jan. 28, 2016

(30) Foreign Application Priority Data
Feb. 5, 2015 (JP) 2015-020963

(51) Int. Cl. H01L 27/32

(52) U.S. Cl. CPC H01L 27/3272; H01L 27/3246

(57) ABSTRACT

An organic EL device includes a first pixel electrode and a second pixel electrode; a functional layer provided on the first pixel electrode and the second pixel electrode; an electrode provided on the functional layer; a sealing layer formed on the electrode; and a light blocking layer provided on an upper layer of the protective layer. The light blocking layer has carbon with an SP2 structure.

### BACKGROUND

1. Technical Field

The present invention relates to an organic EL device and an electronic apparatus.

2. Related Art

The organic electroluminescence (EL) device has a structure in which a light emitting layer formed from a light emitting material is interposed between an anode (pixel electrode) and a cathode (counter electrode). The organic EL device is mounted to a head mounted display (HMD) or an electronic view finder (EVF) or the like as an electronic apparatus.

JP-A-2014-89804 discloses an organic EL device with a structure having a color filter, and a light blocking layer (convexity) provided between colored layers that configure the color filter. A material with light blocking properties, such as aluminum, is used for the light blocking layer.

However, in a case where a color filter is provided, a problem arises where the luminance is lowered (insufficient) when applied to an HMD or the like. In a case in which the color filter is removed, a problem arises where the tone is insufficient when applied to an EVF or the like. In a case where the color filter is removed, a problem arises where light reflected by the light blocking layer is not absorbed by the color filter and cross-talk (stray light) is generated.

### SUMMARY

The invention can be realized in the following aspects or application examples.

### Application Example 1

According to this application example, there is provided an organic EL device, including a substrate; a first pixel electrode and a second pixel electrode on the substrate; an organic light emitting layer provided on the first pixel electrode and the second pixel electrode; an electrode provided on the organic light emitting layer; a protective layer formed from at least one layer and provided on the electrode; a light blocking layer provided on an upper layer of the protective layer. The light blocking layer is provided at a position between the first electrode and the second electrode and has carbon with an SP2 structure.

According to the application example, since light can be absorbed by using a light blocking layer having carbon with an SP2 structure, in other words, light is not easily reflected, even if a color filter is not provided, cross-talk (stray light) can be suppressed from occurring. In a case where a color filter is not provided, it is possible to suppress the luminance from lowering.

### Application Example 2

In the organic EL device according to the application example, it is preferable that the light blocking layer is a graphene laminate film.

According to the application example, since the graphene laminate film is used as the light blocking layer, visible light can be absorbed, and the light blocking layer may be caused to function as high light absorbent film through using the laminate film. As a result, it is possible to suppress stray light from occurring.

### Application Example 3

In the organic EL device according to the application example, it is preferable that a color filter is provided on an upper layer of the light blocking layer.

According to the application example, since the color filter is arranged on the light blocking layer, in other words, the light blocking layer and the color filter are combined, light emission with a favorable high color region and excellent color field of view may be performed, and may be favorably applied to the EVE.

### Application Example 4

In the organic EL device according to the application example, it is preferable that a convexity having optical transparency is provided on the light blocking layer.

According to the application example, since the convexity is provided on the light blocking layer, in a case of forming the colored layers that configure the color filter for each sub-pixel, the colored layer may be more easily formed between adjacent convexities. Since the layer has optical transparency, it is possible to suppress stray light from occurring.

### Application Example 5

It is preferable that the organic EL device according to the application example further includes a resonance length adjusting layer and a reflection layer provided on a lower layer of the pixel electrode.

According to the application example, since a resonance structure (microcavity structure) including a resonance length adjusting layer and a reflection layer is included, in a case where applied to an HMD, it is possible to execute color display without providing a color filter, and, along therewith, to suppress lowering of the luminance. Meanwhile, in a case where applied to an EVF, it is possible for the tone to be improved through being used by matching the color filter.

### Application Example 6

According to this application example, there is provided an electronic apparatus including the above organic EL device.

According to the application example, since the organic EL device is provided, it is possible to provide an electronic apparatus with a high display quality.

### BRIEF DESCRIPTION OF THE DRAWINGS

The invention will be described with reference to the accompanying drawings, wherein like numbers reference like elements.

FIG. 1 is an equivalent circuit diagram showing an electrical configuration of an organic EL device according to the first embodiment.

FIG. 2 is a schematic plan view showing a configuration of the organic EL device.

FIG. 3 is a schematic plan view showing a sub-pixel arrangement.

FIG. 4 is a schematic sectional view showing the structure of the sub-pixel taken along line IV-IV in FIG. 3.

FIG. 5 is a flowchart showing the method of manufacturing the organic EL device.

FIGS. 6A to 6C are schematic sectional views showing a portion of the manufacturing process from the method of manufacturing an organic EL device.

FIGS. 7D to 7F are schematic sectional views showing a portion of the manufacturing process from the method of manufacturing an organic EL device.

FIG. 8 is a schematic view showing a configuration of a head mounted display as an electronic apparatus.

FIG. 9 is a schematic sectional view showing a structure of an organic EL device (sub-pixel) of the second embodiment.

FIGS. 10A to 100 are schematic sectional views showing a portion of the manufacturing process from the method of manufacturing an organic EL device.

FIG. 11 is a schematic sectional view showing a structure of an organic EL device (sub-pixel) of a third embodiment.

FIGS. 12A to 12D are schematic sectional views showing a portion of the manufacturing process from the method of manufacturing an organic EL device.

### DESCRIPTION OF EXEMPLARY EMBODIMENTS

Below, specific embodiments of the invention will be described according to the drawings. The drawings used are displayed after enlarging or reducing as appropriate in order that the portions described are recognizable.

In the following aspects, for example, if the wording “on a substrate” is disclosed, and there is no special description, a case where arrangement is performed so as to contact the top of the substrate, a case where arrangement is performed via another constituent component on top of the substrate, and a case where a portion is arranged so as to contact the top of the substrate and a portion is arranged via the other constituent component are included.

### First Embodiment

### Organic EL Device

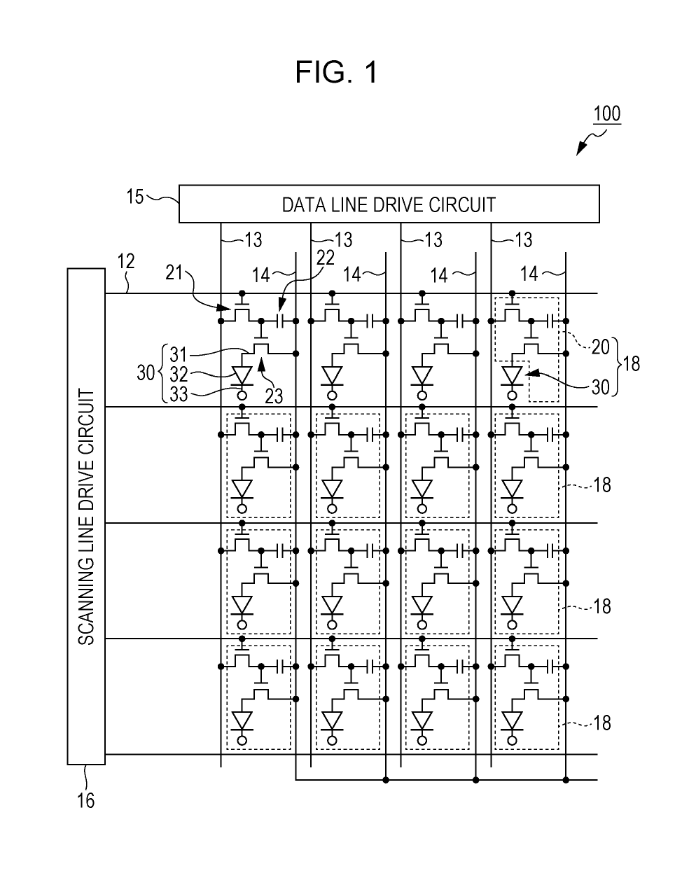

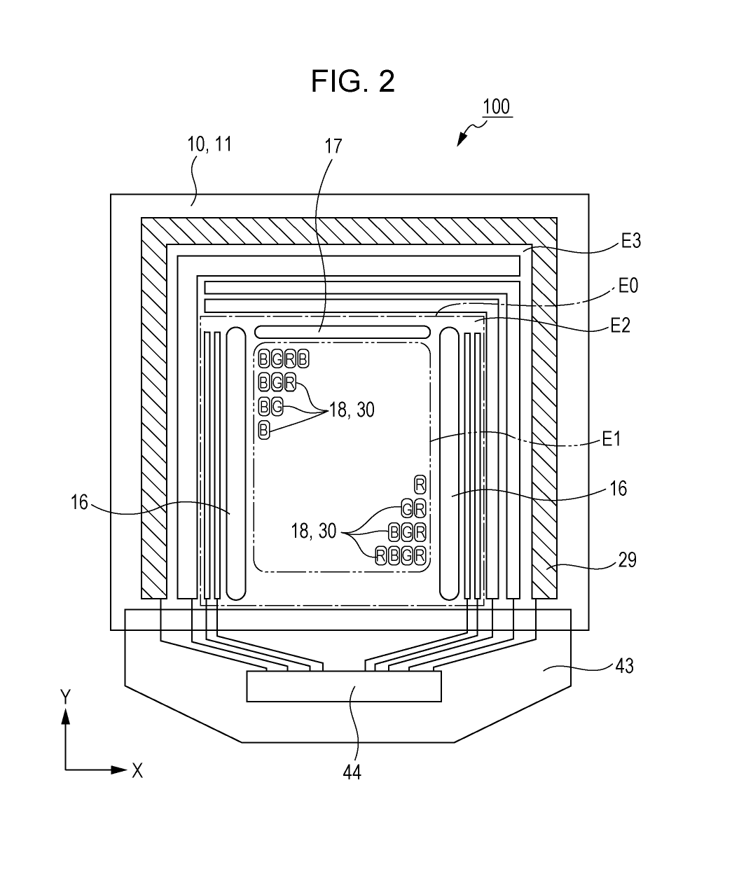

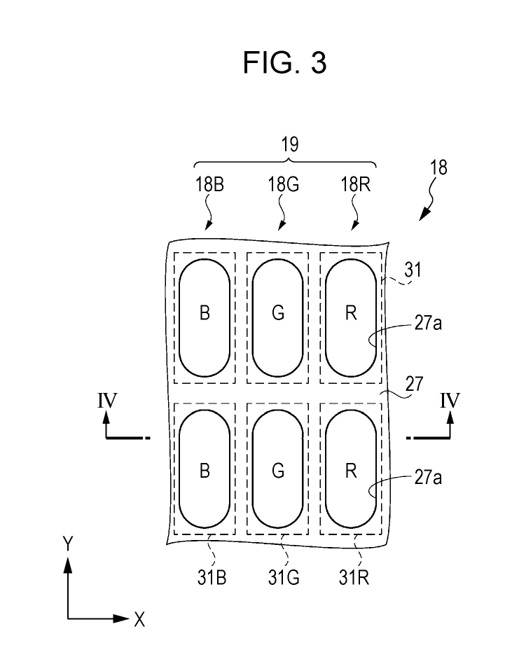

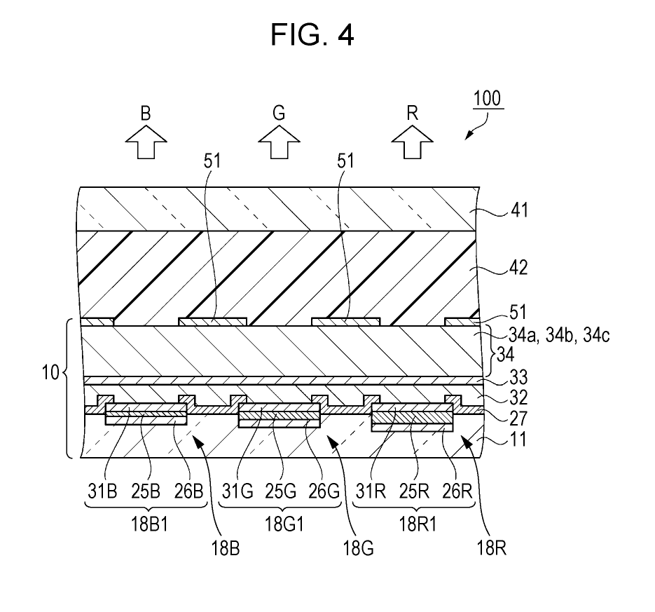

Below, the organic EL device of the embodiment will be described with reference to FIGS. 1 to 4. FIG. 1 is an equivalent circuit diagram showing the electrical configuration of the organic EL device of the first embodiment, FIG. 2 is a schematic plan view showing the configuration of the organic EL device of the first embodiment, FIG. 3 is a schematic plan view showing a sub-pixel arrangement, and FIG. 4 is a schematic sectional view showing the structure of a sub-pixel taken along line IV-IV in FIG. 3.

As shown in FIG. 1, the organic EL device 100 of the embodiment includes plurality of scanning lines 12 and a plurality of data lines 13 that intersect one another, and a plurality of power lines 14 arranged in a line for each of the plurality of data lines 13. The organic EL device includes a scanning line driving circuit 16 to which the plurality of scanning lines 12 is connected, and a data line driving circuit 15 to which the plurality of data lines 13 is connected. A plurality of sub-pixels 18 that is arranged in a matrix form corresponding to each intersection of the plurality of scanning lines 12 and the plurality of data lines 13 is included.

The sub-pixels 18 include an organic EL element 30 as a light emitting element and a pixel circuit 20 that controls the driving of the organic EL element 30.

The organic EL element 30 includes a pixel electrode 31, a counter electrode 33 as a shared electrode, and a functional layer 32 as an organic light emitting layer provided between the pixel electrode 31 and the counter electrode 33. It is possible for such an organic EL element 30 to be electrically denoted as a diode. Although described in detail later, the counter electrode 33 is formed as a shared cathode spanning a plurality of sub-pixels 18.

The pixel circuit 20 includes a switching transistor 21, a storage capacitor 22, and a driving transistor 23. It is possible for the two transistors 21 and 23 to be configured using an n-channel or p-channel thin film transistor (TFT) or a MOS transistor.

The gate of the switching transistor 21 is connected to the scanning line 12, one of the source or drain is connected to the data line 13, and the other of the source or drain is connected to the gate of the driving transistor 23.

One of the source or drain of the driving transistor 23 is connected to the pixel electrode 31 of the organic EL element 30, and the other of the source or drain is connected to the power line 14. The storage capacitor 22 is connected between the gate of the driving transistor 23 and the power line 14.

When the scanning line 12 is driven and the switching transistor 21 thereby enters an on state, and the potential based on the image signal supplied from the data line 13 at this time is held by the storage capacitor 22 via the switching transistor 21.

The on and off states of the driving transistor 23 are determined according to the potential of the storage capacitor 22, that is, the gate potential of the driving transistor 23. When the driving transistor 23 is in the on state, a current with an amount according to the gate potential flows from the power line 14 to the functional layer 32 interposed between the pixel electrode 31 and the counter electrode 33 via the driving transistor 23. The organic EL element 30 emits light according to the current amount flowing to the functional layer 32.

As shown in FIG. 2, the organic EL device 100 includes an element substrate 10. A display region E0 (displayed with a dashed line in the drawing), and a non-display region E3 outside the display region E0 are provided on the element substrate 10. The display region E0 includes an actual display region E1 (displayed with a double dashed line in the drawing) and a dummy region E2 that surrounds the actual display region E1.

The sub-pixels 18 as light emitting pixels are arranged in a matrix form in the actual display region E1. The sub-pixel 18 is provided with the organic EL element 30 as the above-described light emitting element, and is configured so that emitted light with any color from blue (B), green (G), and red (R) is obtained according to the operation of the switching transistor 21 and the driving transistor 23.

In the embodiment, the sub-pixels 18 from which the same color of light emission is obtained are arranged in a first direction, and the sub-pixels 18 from which different colors of light emission is obtained are arranged in a second direction that intersects (orthogonal to) the first direction, which is a so-called stripe format of the arrangement of sub-pixels 18. Below, description is made with the first direction as the Y direction and the second direction as the X direction. The arrangement of the sub-pixels 18 on the element substrate 10 is not limited to the stripe format, and may be a mosaic format or a delta format.

A peripheral circuit for mainly causing the organic EL element 30 of each sub-pixel 18 to emit light is provided in the dummy region E2. As shown in FIG. 2, a pair of scanning line driving circuits 16 is provided extending in the Y direction at positions interposing the actual display region E1 in the X direction. A scanning circuit 17 is provided at a position along the actual display region E1 between the pair of scanning line driving circuits 16.

A flexible circuit substrate (FPC) 43 for achieving electrical connection with an external driving circuit is provided on one edge portion (downward edge portion in drawing) parallel to the X direction of the element substrate 10. A driving IC 44 connected to a peripheral circuit on the element substrate 10 side via the wiring of the FPC 43 is mounted to the FPC 43. The driving IC 44 includes the data line driving circuit 15 described above, and the data line 13 and power line 14 on the element substrate 10 side are connected to the driving IC 44 via the flexible circuit substrate 43.

A wiring 29 for providing a potential to the counter electrode 33 of the organic EL element 30 of each sub-pixel 18 is formed between the outer edges of the display region E0 and the element substrate 10, that is, in the non-display region E3. The wiring 29 is provided on the element substrate 10 so as to surround the display region E0 except for the edge portion of the element substrate 10 to which the FPC 43 is connected.

Next, the parallel arrangement of the sub-pixels 18, particularly the parallel arrangement of the pixel electrode 31 will be described with reference to FIG. 3. As shown in FIG. 3, the sub-pixel 18B from which blue (B) light emission is obtained, the sub-pixel 18G from which green (G) light emission is obtained, and the sub-pixel 18R from which red (R) light emission is obtained are arranged in parallel in this order in the X direction. The sub-pixels 18 from which the same color of light emission is obtained are arranged in parallel adjacent in the Y direction. The configuration performs display with the three sub-pixels 18B, 18G, and 18R arranged in parallel in the X direction as one pixel 19.

The arrangement pitch of the sub-pixels 18B, 18G, and 18R in the X direction is less than 5 μm. The sub-pixels 18B, 18G, and 18R are arranged spaced with a gap of 0.5 μm to 1.0 μm in the X direction. The arrangement pitch of the sub-pixels 18B, 18G, and 18R in the Y direction is less than 10 μm.

The pixel electrodes 31 in the sub-pixels 18 are substantially rectangular, and the long direction thereof is arranged along the Y direction. The pixel electrodes 31 are referred to as the pixel electrodes 31B, 31G, and 31R corresponding to the light emission color. An insulating film 27 is formed covering the outer edge of each pixel electrode 31B, 31G, and 31R. Thereby, an opening portion 27a is formed on each pixel electrode 31B, 31G, and 31R, and the pixel electrodes 31B, 31G, and 31R are exposed in the respective opening portions 27a. The planar shape of the opening portion 27a is also substantially rectangular.

In FIG. 3, although the arrangement of the sub-pixels 18B, 18G, and 18R with different colors is in the order of blue (B), green (G), and red (R) from the left side in the X direction, there is no limitation thereto. The order may also be red (R), green (G), and blue (B) from the left side in the X direction.

Next, the structure of the sub-pixels 18B, 18G, and 18R will be described with reference to FIG. 4. As shown in FIG. 4, the organic EL device 100 includes a base material 11 as a substrate in the invention, a first pixel electrode layer 18B1, a second pixel electrode layer 18G1, and a third pixel electrode layer 1881 formed on the base material 11, a functional layer 32, and a counter electrode 33.

A sealing layer 34 as a protective layer, a light blocking layer 51 formed on the sealing layer 34, a filler layer 42 formed so as to cover the light blocking layer 51 and the sealing layer 34, and a counter substrate 41 arranged on the filler layer 42 are provided on the counter electrode 33.

The element substrate 10 includes the base material 11 to the light blocking layer 51. In FIG. 4, the configuration of the driving transistor 23 or the like of the pixel circuit 20 on the element substrate 10 is not shown in the drawing.

The organic EL device 100 employs a top emission format in which light emitted from the functional layer 32 is extracted from the counter substrate 41 side. Accordingly, it is possible for the base material 11 to use not only a transparent substrate, such as glass, but also a non-transparent substrate, such as silicon or a ceramic. The counter substrate 41 is a transparent substrate, such as glass.

Reflection layers 26 (26B, 26G, and 26R), transparent layers 25 (25B, 25G, 25R) as resonance length adjusting layers, and pixel electrodes 31 (31B, 31G, 31R) are formed in order from the base material 11 side for the first pixel electrode layer 18B1, the second pixel electrode layer 18G1, and the third pixel electrode layer 18R1.

It is possible for Al (aluminum), Ag (silver) or alloys of these metals having optical reflectivity to be used for the reflection layer 26.

The transparent layer 25 serves a role as a resonance length adjusting layer, described later. The transparent layer 25 achieves electrical insulation between the pixel electrode 31 and the reflection layer 26, which is formed later, and it is possible for an inorganic insulating film such as SiOx (silicon dioxide) to be used. The film thickness of the transparent layer 25 differs at each of the first pixel electrode layer 18B1, the second pixel electrode layer 1861, and the third pixel electrode layer 18R1.

Specifically, the film thickness becomes thicker in the order of blue (B), green (G), and red (R). In other words, the film thickness of the transparent layer 25 differs corresponding to the sub-pixels 18B, 18G, and 18R.

The pixel electrodes 31B, 31G, and 31R are formed from a transparent conductive film, such as ITO (Indium Tin Oxide) or IZO (Indium Zinc Oxide).

The functional layer 32 includes an organic light emitting layer from which white light is obtained, and is formed in common spanning the sub-pixels 18B, 18G, and 18R. It is possible to realize the white light by combining the organic light emitting layers from which blue (B), green (G), and red (R) emitted light are obtained. Even if organic light emitting layers from which blue (B) and yellow (Y) light emission are obtained are combined, it is possible to obtain a pseudo-white light.

The counter electrode 33 that covers the functional layer 32 is formed from an MgAg (magnesium silver) alloy, and the film thickness is controlled so that both optical transparency and optical reflectivity are provided.

The sealing layer 34 has a structure in which the first sealing layer 34a, the planarizing layer 34b, and the second sealing layer 34c are layered in this order from the counter electrode 33 side.

The first sealing layer 34a and the second sealing layer 34c are formed using an inorganic material. Examples of the inorganic material include SiOx (silicon oxide), SiNx (silicon nitride), SiOxNy (silicon oxynitride), and AlxOy (aluminum oxide) through which moisture and oxygen does not easily pass. Examples of the method of forming the first sealing layer 34a and the second sealing layer 34c include a vacuum deposition method, an ion plating method, a sputtering method, and a chemical vapor deposition (CVD).

In terms of not imparting heat damage or the like to the organic EL element 30, it is preferable to employ a vacuum deposition method or an ion plating method. The film thickness of the first sealing layer 34a and the second sealing layer 34c is 50 nm to 1000 nm, and preferably 200 nm to 400 nm so that cracks and the like are not easily formed and transparency is obtained during film formation.

The planarizing layer 34b has transparency, and it is possible to form the layer using any resin material of a thermal or ultraviolet-curable epoxy resin, an acrylic resin, a urethane resin, and a silicon resin. The layer may be formed using a coating-type inorganic material (silicon oxide or the like).

The planarizing layer 34b is formed by being layered on the first sealing layer 34a covering the plurality organic EL elements 30. Since roughness arises in the surface of the first sealing layer 34a influenced by the lower layer, it is preferable for the planarizing layer 34b to be formed with a film thickness of 1 μm to 5 μm in order to relieve the roughness.

The second sealing layer 34c covering the planarizing layer 34b is formed using the above-described inorganic materials. The light blocking layer 51 is provided between the different colors of sub-pixels 18B, 18G, and 18R on the sealing layer 34.

The light blocking layer 51 is a material having carbon with an SP2 structure as a main component, and, for example, is graphene. The light blocking layer 51 uses a thin film of graphene with an atomic layer film thickness of several tens to several hundreds of atoms.

A one atom-thick thin film (layer) of graphene has optical transmissivity with an absorption of 2% to 3%. Thus, transmissivity is substantially eliminated if several tens to several hundreds of atoms (layer) are layered. The film thickness is several nm to several tens of nm.

In the related art, although an adverse influence is exerted on the transmission of light when the height of the light blocking layer is approximately 1 μm, it is possible for the exertion of the adverse influence to be suppressed as long as the film thickness is several nm to several tens of nm.

By layering thin films in this way, it is possible for the optical transmissivity to be lowered. There is no limitation to graphene, and carbon nanotubes or fullerene may be used.

The organic EL device 100 of the embodiment includes an optical resonator configured between the reflection layer 26 and the counter electrode 33. Though the film thickness of the transparent layer 25 (25B, 25G, 25R) being difference for each sub-pixel 18B, 18G, and 18R, the optical distance in each of the respective resonators is different. In so doing, a structure is used in which light with a resonance length corresponding to each color in the respective sub-pixels 18B, 18G, and 18R is obtained.

The adjustment method of the optical distance in the optical resonator is not limited thereto, and the film thickness of the pixel electrodes 31 (31B, 31G, 31R) on the base material 11 may be made different for each sub-pixel 18B, 18G, 18R. The resonant light emitted from the optical resonator of each sub-pixel 18B, 18G, and 18R is radiated from the transparent counter substrate 41 side.

### Method of Manufacturing Organic EL Device

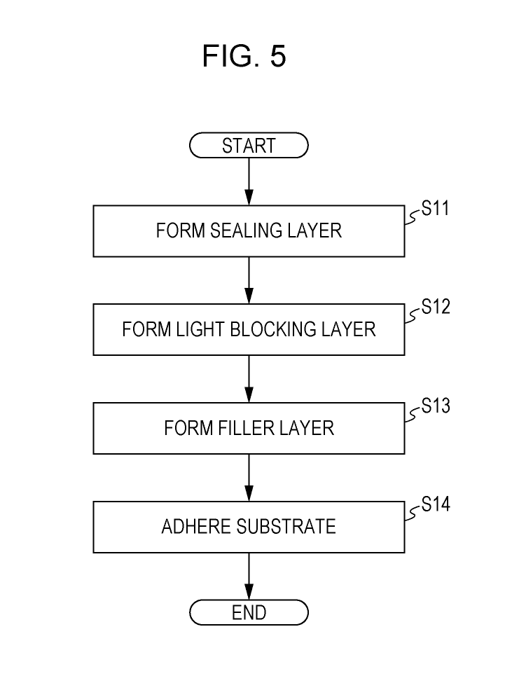

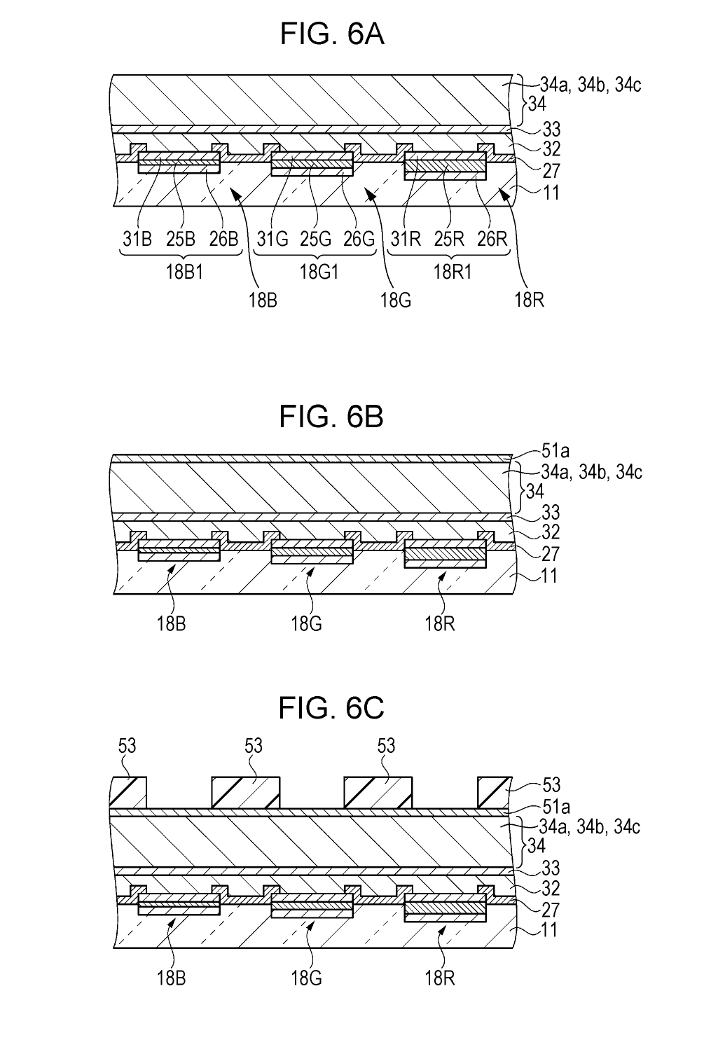

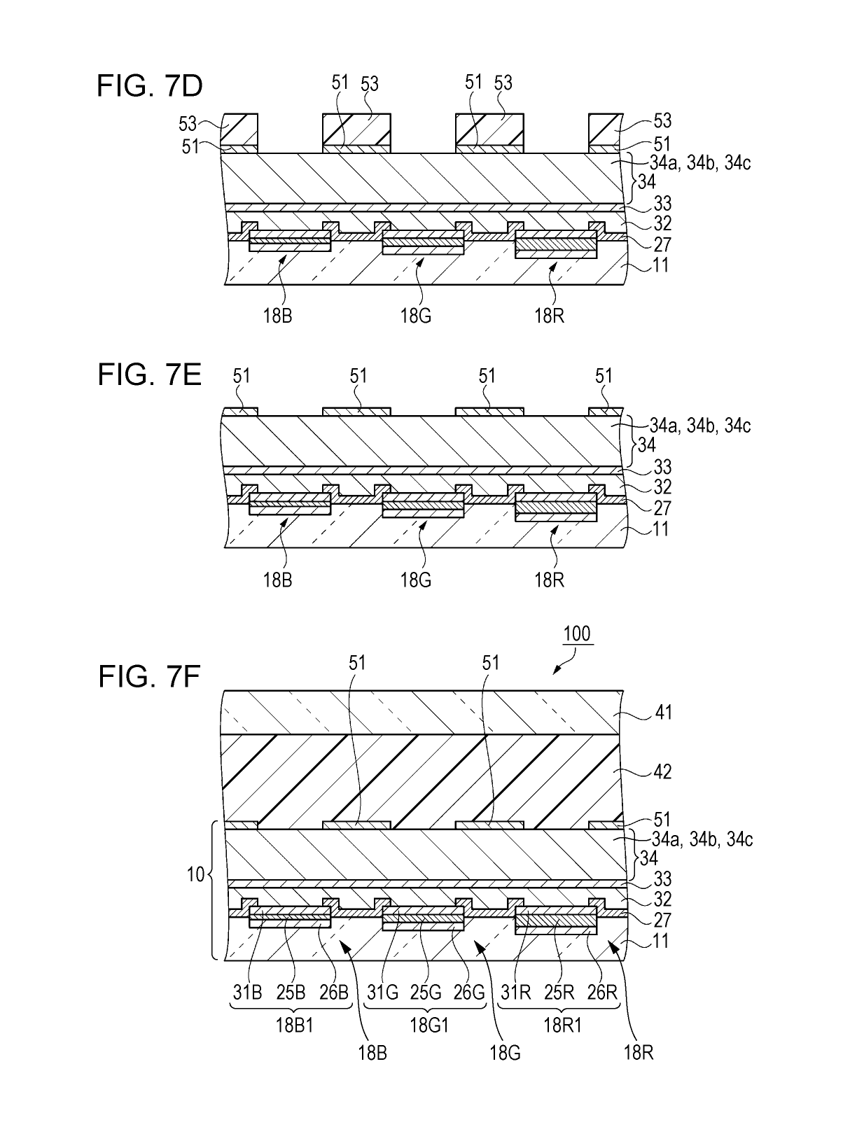

Next, the method of manufacturing the organic EL device of the first embodiment will be described with reference to FIGS. 5 to 7. FIG. 5 is a flowchart showing the method of manufacturing the organic EL device. FIGS. 6 and 7 are schematic cross-sectional views showing a portion of the manufacturing process from the method of manufacturing the organic EL device.

As shown in FIG. 5, the method of manufacturing the organic EL device 100 of the embodiment includes a sealing layer forming process (step S11), a light blocking layer forming process (step S12), a filler layer forming process (step S13), and a substrate adhering process (step S14). It is possible for the method of forming the pixel circuit 20, the organic EL element 30 or the like on the base material 11 to employ known methods.

Accordingly, in FIGS. 6A to 7F, the configuration of the driving transistor 23 of the pixel circuit 20 and the like on the base material 11 is not displayed. Hereinafter, the step S12 that is a characteristic part of the invention will be intensively described.

First, as shown in FIG. 5, in step S11, the sealing layer 34 is formed. Specifically, as shown in FIG. 6A, the first sealing layer 34A is formed so as to cover the counter electrode 33, the planarizing layer 34b is formed on the first sealing layer 34a, and the second sealing layer 34c is formed on the planarizing layer 34b.

As described above, the first sealing layer 34a and the second sealing layer 34c are formed using an inorganic material, such as silicon oxide or the like. Examples of the method of forming the first sealing layer 34a and the second sealing layer 34c include a vacuum deposition method. The film thickness of the first sealing layer 34a and the second sealing layer 34c is approximately 200 nm to 400 nm.

As a method of forming the planarizing layer 34b, the planarizing layer 34b formed from an epoxy resin is formed by using a solution including an epoxy resin having transparency and a solvent of the epoxy resin, and coating and drying the solution with a printing method or a spin coating method. The film thickness of the planarizing layer 34b is 1 μm to 5 μm.

In the step S12, the light blocking layer 51 is formed between the different colors of sub-pixels 18B, 18G, and 18R on the sealing layer 34. Specifically, first, as shown in FIG. 6B, a thin film of the light blocking layer 51a formed from graphene is formed over the entire surface of the sealing layer 34. It is possible for a CVD method to be used as the film forming method. The film thickness of the light blocking layer 51a is several nm to several tens of nm, as described above.

Next, as shown in FIG. 6C, a resist pattern 53 is formed on the light blocking layer 51a. Specifically, the resist pattern 53 is formed between the sub-pixels 18B, 18G, and 18R using a photolithography method.

Next, as shown in FIG. 7D, the light blocking layer 51a is subjected to an etching process. Specifically, the light blocking layer 51a is subjected to an etching process with the resist pattern 53 as a mask.

Next, as shown in FIG. 7E, the resist pattern 53 is removed. Specifically, the light blocking layer 51 is completed by removing the resist pattern 53 using an ashing method.

There is no limitation to forming the light blocking layer 51 using the photolithography method, and the layer may be formed using a lift-off method. Since the light blocking layer 51 of several nm to several tens of nm is formed, it is possible for the workability to be improved. It is possible to form a light blocking layer 51 with high light blocking properties (light absorbing properties) while being a thin film.

In the step S13, a material that becomes the filler layer 42 is coated. Specifically, as shown in FIG. 7F, a transparent resin material having adhesiveness is coated so as to cover the light blocking layer 51 and the sealing layer 34. The transparent resin material is, for example, a thermosetting epoxy resin. The thickness of the filler layer 42 is approximately 10 μm to 100 μm.

Next, in the step S14, the counter substrate 41 is adhered. Specifically, as shown in FIG. 7F, the counter substrate 41 is arranged at a predetermined position facing the base material 11 having the coated filler layer 42, and the counter substrate 41 is pressed to the base material 11 side. In so doing, the element substrate 10 and the counter substrate 41 are adhered.

### Electronic Apparatus

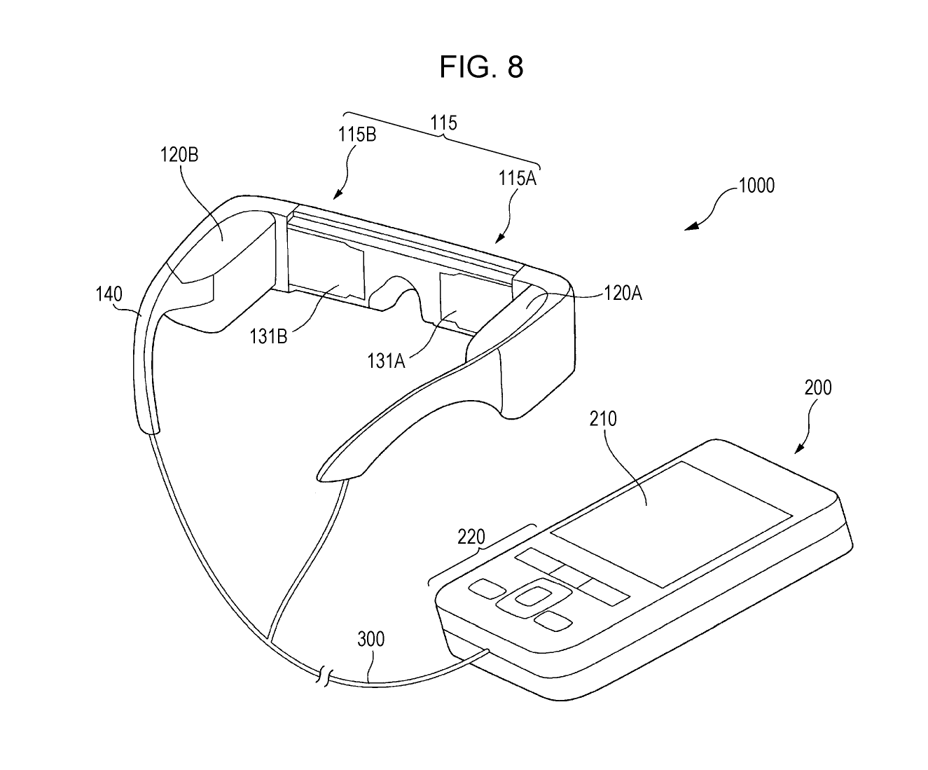

Next, an electronic apparatus according to the embodiment will be described with reference to FIG. 8. FIG. 8 is a schematic view showing a configuration of a head mounted display (HMD) as an electronic apparatus.

As shown in FIG. 8, the head mounted display 1000 is provided with the above-described organic EL device 100, and is provided with a main body section 115 having a glasses shape, and a controller 200 having a size enough to be held in the hand of a user.

The main body section 115 and the controller 200 are connected to be able to communicate in a wired or wireless manner. In the embodiment, the main body section 115 and the controller 200 are connected to be able to communicate with a cable 300. The main body section 115 and the controller 200 communicate image signals or control signals via the cable 300.

The main body section 115 is provided with a right eye display unit 115A and a left eye display unit 115B. The right eye display unit 115A is provided with an image forming unit 120A that forms image light of a right eye image. The left eye display unit 115B is provided with an image forming unit 120B that forms image light of a left eye image.

The image-forming unit 120A is accommodated in temple part (right side) of the glasses in the glasses-type main body section 115. Meanwhile, the image-forming unit 120B is accommodated in temple part (left side) of the glasses in the glasses-type main body section 115.

A viewing portion 131A having optical transparency is provided in the main body section 115. The viewing portion 131A radiates image light of the right eye image toward the right eye of the user. In the head mounted display 1000, the viewing portion 131A has optical transparency, and the periphery is visible via the viewing portion 131A.

A viewing portion 131B having optical transparency is provided in the main body section 115. The viewing portion 131B radiates image light of the left eye image toward the left eye of the user. In the head mounted display 1000, the viewing portion 131B has optical transparency, and the periphery is visible via the viewing portion 131B.

The controller 200 includes an operation unit 210 and operation buttons 220. The user performs operation input with respect to the operation unit 210 or the operation button unit 220 of the controller 200, and performs instruction to the main body section 115.

In addition to the head mounted display 1000, it is possible to use various electronic apparatuses such as a head up display (HUD), a picoprojector, a smartphone, a mobile telephone, a mobile computer, a digital camera, a digital video camera, a vehicle-mounted apparatus, and a lighting apparatus as the electronic apparatus to which the organic EL device 100 is mounted.

As described in detail above, according to the organic EL device 100 and electronic apparatus of the first embodiment, the effects shown below are obtained.

(1) According to the organic EL device 100 of the first embodiment, since light can be absorbed by using a layered film having carbon with an SP2 structure as a main component as the light blocking layer 51, in other words, light is not easily reflected, even if a color filter is not provided, cross-talk (stray light) can be suppressed from occurring. In other words, it is possible for the graphene laminate film to be made to function as a high light absorbency film. Since the color filter is not provided, it is possible to suppress the luminance from lowering.

(2) According to the organic EL device 100 of the first embodiment, since the light blocking layer 51 with a thickness of several nm to several tens of nm is formed and subjected to etching process, it is possible for the workability to be comparatively improved.

(3) According to the organic EL device 100 of the first embodiment, since a resonance structure (microcavity structure) is included, in a case where applied to a see-through type head mounted display 1000, it is possible for the color display to be performed without providing a color filter, and, since no color filter is provided, it is possible for lowering of the luminance to be suppressed. Additionally, in a case of providing a color filter, it is possible to suppress damage being imparted on the organic EL element 30 due to setting an extremely high luminance. As a result, it is possible for the service life of the organic EL element 30 to be extended.

(4) According to the electronic apparatus according to the first embodiment, since the organic EL device 100 is provided, it is possible to provide an electronic apparatus with a high display quality.

### Second Embodiment

### Organic EL Device

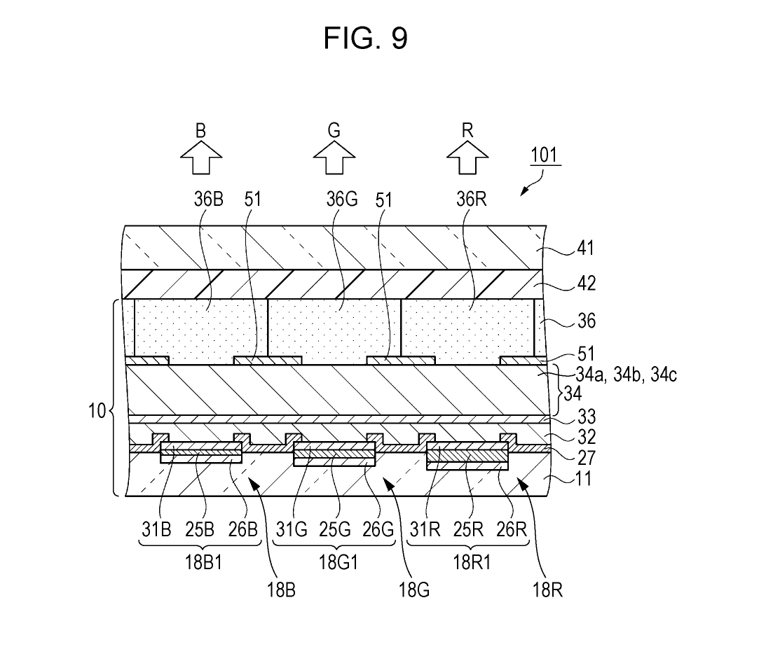

Next, the organic EL device of the second embodiment will be described with reference to FIG. 9. FIG. 9 is a schematic sectional view showing a structure of an organic EL device (sub-pixel) of the second embodiment.

Compared to the organic EL device 100 of the above-described first embodiment, the organic EL device 101 of the second embodiment differs in the parts provided with a color filter 36 and the other parts are substantially the same. Therefore, in the second embodiment, the parts different to the first embodiment will be described in detail, and the other overlapping parts will not be described, as appropriate.

As shown in FIG. 9, the color filter 36 of the organic EL device 101 of the second embodiment is provided so as to cover the light blocking layer 51 and the sealing layer 34. Similarly to the first embodiment, the filler layer 42, and the counter substrate 41 are arranged on the color filter 36. The element substrate 10 of the embodiment includes from the base material 11 to the color filter 36.

The light emitted from the functional layer 32 of the organic EL device 101 of the second embodiment passes through the color filter 36 and is extracted from the counter substrate 41 side. Since the color filter 36 alleviates the roughness with the planarizing layer 34b that configures the sealing layer 34, little influence of the roughness is imparted.

The color filter 36 is configured to include the blue (B), green (G), and red (R) colored layers 36B, 36G, 36R formed on the sealing layer 34 with a photolithography method. The colored layers 36B, 36G, and 36R are formed corresponding to the sub-pixels 18B, 18G, and 18R.

On the sealing layer 34, the light blocking layer 51 is provided, similarly to the first embodiment, between the colored layers 36B, 36G, and 36R of the different colored sub-pixels 18B, 18G, and 18R. The resonant light emitted from the optical resonator of each sub-pixel 18B, 18G, and 18R passes through each colored layer 36B, 36G, and 36R, and is thereby radiated from the transparent counter substrate 41 side.

### Method of Manufacturing Organic EL Device

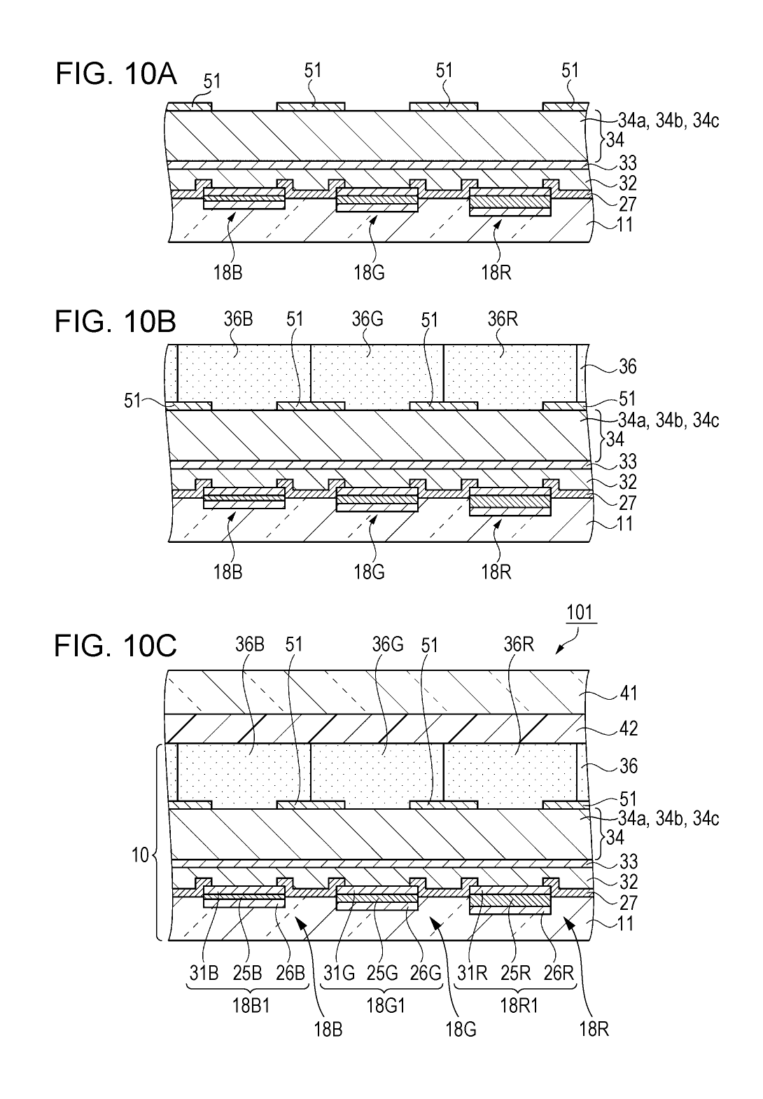

Next, the method of manufacturing the organic EL device of the second embodiment will be described with reference to FIGS. 10A to 100. FIGS. 10A to 100 are schematic sectional views showing a portion of the manufacturing process from the method of manufacturing an organic EL device.

The formation process of the color filter of the method of manufacturing the organic EL device 101 of the second embodiment is performed between the processes in the steps S12 and S13 in the method of manufacturing the organic EL device 100 of the first embodiment. Accordingly, in FIG. 10, the processes before and after including the method of manufacturing the color filter 36 will be intensively described.

First, as shown in FIG. 10A, up to forming the light blocking layer 51 on the sealing layer 34 is performed similarly to the first embodiment. Thereafter, as shown in FIG. 10B, the color filter 36 is formed.

Specifically, a light sensitive resin material including a green coloring material is coated on the surface of the sealing layer 34 on which the light blocking layer 51 is formed by a spin coating method, thereby forming a light sensitive resin layer. Thereafter, by exposing or developing the light sensitive resin layer, a colored layer 36G is formed between the light blocking layers 51 positioned above the pixel electrode 31G.

Next, a light sensitive resin material including a blue coloring material is coated using the spin coating method, thereby forming a light sensitive resin layer. Thereafter, by exposing or developing the light sensitive resin layer, a colored layer 36B is formed.

Next, a light sensitive resin material including a red coloring material is coated using the spin coating method, thereby forming a light sensitive resin layer. Thereafter, by exposing or developing the light sensitive resin layer, a colored layer 36R is formed.

In so doing, as shown in FIG. 10B, the colored layer 36B is formed above the pixel electrode 31B, the colored layer 36G is formed above the pixel electrode 31G, and the colored layer 36R is formed above the pixel electrode 31R.

Thereafter, as shown in FIG. 100, the material of the filler layer 42 is coated on the color filter 36, similarly to the first embodiment. Next, the counter substrate 41 is adhered. In so doing, the organic EL device 101 of the second embodiment is completed.

As described in detail above, according to the organic EL device 101 in the second embodiment, the effects shown below are obtained.

(5) According to the organic EL device 101 of the second embodiment, since the color filter 36 is provided on the light blocking layer 51 and the sealing layer 34, in other words, the light blocking layer 51 and the color filter 36 are combined, it is possible for light with a favorable high color region and excellent color field of view to be emitted, and application to an EVF or the like not easily influenced by the luminance is possible. Favorable application to a closed-type head mounted display is also possible.

### Third Embodiment

### Organic EL Device

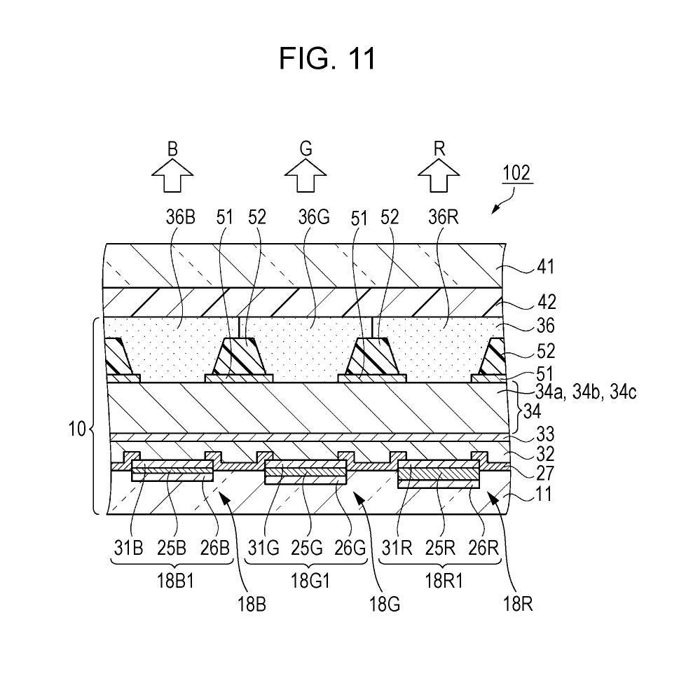

Next, the organic EL device of the third embodiment will be described with reference to FIG. 11. FIG. 11 is a schematic cross-sectional view showing a structure of an organic EL device (sub-pixel) of the third embodiment.

Compared to the organic EL device 101 of the above-described second embodiment, the organic EL device 102 of the third embodiment differs in the parts at which the convexity 52 is provided on the light blocking layer 51, and the other parts are substantially the same. Therefore, in the third embodiment, the parts different to the second embodiment will be described in detail, and the other overlapping parts will not be described, as appropriate.

As shown in FIG. 11, a convexity 52 with a trapezoidal section is formed between each colored layer 36B, 36G, and 36R of the color filter 36 on the light blocking layer 51 of the organic EL device 102 of the third embodiment.

Specifically, the convexities 52 are arranged on a part adjacent to the blue colored layer 36B and the green colored layer 36G, a part adjacent to the green colored layer 36G and the red colored layer 36R, and a part adjacent to the red colored layer 36R and the blue colored layer 36B.

The convexity 52 is formed by a light sensitive resin material not including a coloring material having optical transparency. That is, the main material of the convexity 52 and the colored layers 36B, 36G, and 36R is the same.

The color filter 36 of the organic EL device 102 is provided so as to cover the light blocking layer 51, the convexity 52, and the sealing layer 34. The filler layer 42 and the counter substrate 41 are arranged on the color filter 36. The element substrate 10 of the embodiment includes from the base material 11 to the color filter 36.

### Method of Manufacturing Organic EL Device

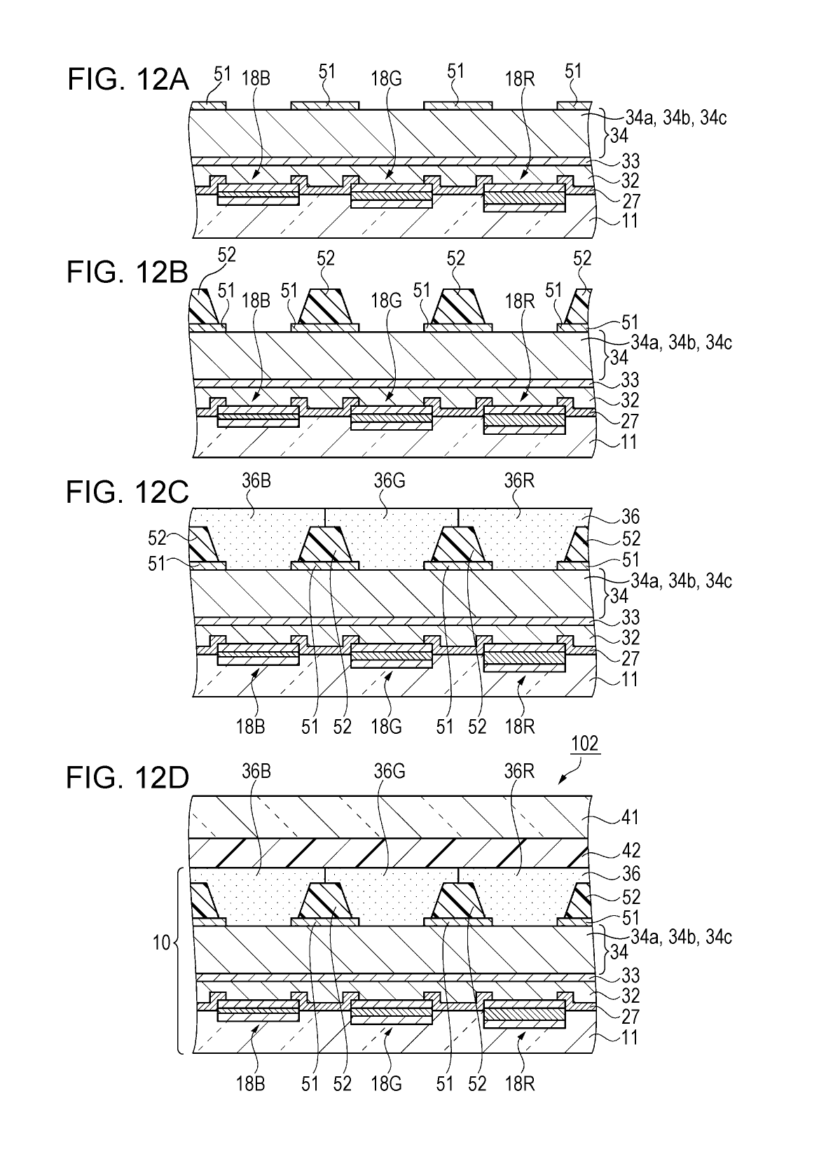

Next, the method of manufacturing the organic EL device of the third embodiment will be described with reference to FIGS. 12A to 12D. FIGS. 12A to 12D are schematic sectional views showing a portion of the manufacturing process from the method of manufacturing an organic EL device.

The method of manufacturing the organic EL device 102 of the third embodiment forms the convexity 52 before the formation process of the color filter 36 in the method of manufacturing the organic EL device 101 of the second embodiment. Accordingly, in FIG. 12, the processes before and after including the method of manufacturing the convexity 52 will be intensively described.

As shown in FIG. 12A, up to forming the light blocking layer 51 on the sealing layer 34 is performed similarly to the second embodiment. Thereafter, as shown in FIG. 12B, the convexity 52 is formed.

Specifically, a transparent light sensitive resin layer is formed by coating a transparent light sensitive resist with a spin coating method, and drying the resist. The transparent light sensitive resin layer is configured by a light sensitive acrylic resin, and the region irradiated with (exposed to) light is made insoluble.

Next, the light sensitive resin material that is made insoluble is baked and cured, thereby forming the trapezoidal convexity 52 on the light blocking layer 51. The light sensitive resin layer becomes a transparent resin with increased transparency by being irradiated with (exposed to) light.

Thereafter, a light sensitive resin material including a green coloring material is coated on the surface of the sealing layer 34 on which the convexity 52 and the light blocking layer 51 are formed with a spin coating method, thereby forming a light sensitive resin layer. Thereafter, by exposing or developing the light sensitive resin layer, a colored layer 36G is formed between the convexities 52 positioned above the pixel electrode 31G.

Next, a light sensitive resin material including a blue coloring material is coated using the spin coating method, thereby forming a light sensitive layer. Thereafter, by exposing or developing the light sensitive resin layer, a colored layer 36B is formed.

Next, a light sensitive resin material including a red coloring material is coated using the spin coating method, thereby forming a light sensitive resin layer. Thereafter, by exposing or developing the light sensitive resin layer, a colored layer 36R is formed.

In so doing, as shown in FIG. 12C, the colored layer 36B is formed between the convexities 52 positioned above the pixel electrode 31B, the colored layer 36G is formed between the convexities 52 positioned above the pixel electrode 31G, and the colored layer 36R is formed between the convexities 52 positioned above the pixel electrode 31R.

Thereafter, as shown in FIG. 12D, the material of the filler layer 42 is coated on the color filter 36. Next, the counter substrate 41 is adhered. In so doing, the organic EL device 102 of the third embodiment is completed.

As described in detail above, according to the organic EL device 102 of the third embodiment, the effects shown below are obtained.

(6) According to the organic EL device 102 of the third embodiment, since the convexity 52 is provided on the light blocking layer 51, in a case of forming the colored layers 36B, 36G, and 36R that configure the color filter 36 for each sub-pixel 18B, 18G, and 18R, it is possible for the colored layers 36B, 36G, 36R to be more easily formed between adjacent convexities 52. Since the layer has optical transparency, stray light does not easily occur.

The aspects of the invention are not limited to the above-described embodiments and are able to be appropriately changed within a range not departing from the gist or spirit of the invention read from the claims and the entire specification, and are included in the technical range of the aspects of the invention. It is possible to execute the embodiments as follows.

### Modification Example 1

In this way, although the organic EL devices 100, 101, and 102 are provided with a resonance structure (microcavity structure), there is no limit thereto, and a structure may be used in which the resonance structure is not provided.

The entire disclosure of Japanese Patent Application No.: 2015-020963, filed Feb. 5, 2015 is expressly incorporated by reference herein.

What is claimed is:

1. An organic EL device, comprising:
a substrate;
a first pixel electrode and a second pixel electrode on the substrate;
an organic light emitting layer provided on the first pixel electrode and the second pixel electrode;
an electrode provided on the organic light emitting layer;
a protective layer formed from at least one layer and provided on the electrode; and
a light blocking layer provided on an upper layer of the protective layer,
wherein the light blocking layer is provided at a position between the first pixel electrode and the second pixel electrode,
wherein the light blocking layer has carbon with an SP2 structure.

2. The organic EL device according to claim 1,
wherein the light blocking layer is a graphene laminate film.

3. The organic EL device according to claim 1,
wherein a color filter is provided on an upper layer of the light blocking layer.

4. The organic EL device according to claim 3,
wherein a convexity having optical transparency is provided on the light blocking layer.

5. The organic EL device according to claim 1, further comprising:
a resonance length adjusting layer and a reflection layer provided on a lower layer of the pixel electrode.

6. An electronic apparatus comprising:
the organic EL device according to claim 1.

7. An electronic apparatus comprising:
the organic EL device according to claim 2.

8. An electronic apparatus comprising:
the organic EL device according to claim 3.

9. An electronic apparatus comprising:
the organic EL device according to claim 4.

10. An electronic apparatus comprising:
the organic EL device according to claim 5.
